(19) United States
(12) Patent Application Publication
(10) Pub. No.: US 2025/0139309 A1
(43) Pub. Date: May 1, 2025

(54) Temperature and Voltage Profiling Computer Systems and Methods

(71) Applicant: Arm Limited, Cambridge (GB)

(72) Inventors: Rainer Herberholz, Great Abington (GB); Tirdad Anthony Takeshian, Vence (FR); Amit Chhabra, Delhi (IN); El Mehdi Boujamaa, Valbonne (FR)

(21) Appl. No.: 18/926,127

(22) Filed: Oct. 24, 2024

(30) Foreign Application Priority Data
Oct. 27, 2023 (IN) 202341073253
Apr. 4, 2024 (GB) 2404812.6

(51) Int. Cl. G06F 30/10; G06F 1/20; G06F 1/28

(52) U.S. Cl. CPC G06F 30/10; G06F 1/206; G06F 1/28

(57) ABSTRACT

According to one implementation of the present disclosure, a method of profiling the temperature and voltage across different locations within a processor is disclosed. The method includes: in a first stage, determining respective first and second voltage sensitivity coefficients and respective first and second temperature sensitivity coefficients corresponding to a pair of ring oscillators; and in a second stage, determining a voltage deviation and a temperature deviation from a predetermined reference voltage and a predetermined reference temperature respectively, based on the determined respective first and second voltage sensitivity coefficients and the determined respective first and second temperature sensitivity coefficients.

### FIELD

The present disclosure is generally related to the temperature and voltage profiling computer systems and methods.

### DESCRIPTION

This section is intended to provide background information to facilitate a better understanding of various technologies described herein. As the section's title implies, this is a discussion of related art. That such art is related in no way implies that it is prior art. The related art may or may not be prior art. It should therefore be understood that the statements in this section are to be read in this light, and not as admissions of prior art.

Advances in technology have resulted in smaller and more powerful computing devices including smaller and more powerful digital integrated circuits (ICs). For example, a variety of personal computing devices, including wireless telephones, such as mobile and smart phones, gaming consoles, tablets and laptop computers are small, lightweight, and easily carried by users. These devices can communicate voice and data packets over wireless networks. Further, many such devices incorporate additional functionality, such as a digital still camera, a digital video camera, a digital recorder, and an audio file player. Also, such devices can process executable instructions, including software applications, such as a web browser application, that can be used to access the Internet. As such, these devices can include significant computing and networking capabilities. Other computing devices include routers and other network interconnection devices that may connect various different network resources. For all such computing devices, there is an ever-increasing demand for greater power, performance, and area efficiency, particularly with regard to digital logic within such ICs of the computing devices.

For the supervision of digital ICs (i.e., digital logic ICs) at test, characterization and during operation, temperature sensors may be positioned within a processing unit to monitor the temperature of multiple regions within such a processing unit. These sensors may be used to optimize the system performance, which may involve changing the voltage and/or frequency of the processing unit in order to control power dissipation. The frequency of a ring oscillator is a function of temperature, but it is also strongly dependent on the process skew and voltage. Hence, determining the temperature from the frequency of the ring oscillator would not be straight-forward. One solution to this problem would be to optimize for precision control of the ring oscillator voltage supply such that only temperature can have an impact upon ring oscillator frequency. However, this is not be practical since there may be variations in the voltage value across different regions within the processing unit. Hence, controlling the exact operating voltage of a ring oscillator may be, therefore, not straight-forward. In an alternate implementation, a voltage regulator controlling supply voltage-“ground bounce” (i.e., VDD-transient VSS) would need to be added at each sensor location, and such a solution would not be fully digital, nor would it be easily integrated within the processor unit. Accordingly, there is a need in the art for a solution that is a fully digital, area-efficient design.

### SUMMARY

According to one implementation of the present disclosure, a method of profiling the temperature and voltage across different locations within a processor is disclosed. The method includes: in a first stage, determining respective first and second voltage sensitivity coefficients in a limited range of voltage (i.e., voltage range) and respective first and second temperature sensitivity coefficients in a limited range of temperature (i.e., temperature range) corresponding to a pair of ring oscillators; and in a second stage, determining a voltage deviation from a predetermined reference voltage and the temperature deviation from a predetermined reference temperature based on the determined respective first and second voltage sensitivity coefficients and the determined respective first and second temperature sensitivity coefficients.

According to another implementation of the present disclosure, a computer system (e.g., including a digital integrated circuit) comprising: a processor; and a memory accessible to the processor, the memory storing instructions that are executable by the processor to perform operations comprising: in a first stage, determining respective first and second voltage sensitivity coefficients and respective first and second temperature sensitivity coefficients corresponding to a pair of ring oscillators; and in a second stage, determining a voltage deviation and a temperature deviation from a respective predetermined voltage and a respective predetermined temperature based on the determined respective first and second voltage sensitivity coefficients and the determined respective first and second temperature sensitivity coefficients.

According to another implementation of the present disclosure, a method includes: in a first stage, obtaining, for a pair of ring oscillators of a hotspot profiler of a processing unit (e.g., incorporated in digital IC), a plurality of operating points of a first operating plot, wherein the first operating plot corresponds to a plurality of ring oscillator frequencies as a function of a plurality of supply voltage; in the first stage, obtaining, for the pair of the ring oscillators of the hotspot profiler of the processing unit, a plurality of operating points of a second operating plot, wherein the second operating plot corresponds to the plurality of the ring oscillator frequencies as a function of a plurality of temperatures; in the first stage, determining respective one or more voltage ranges and one or more temperature ranges on the first and second operating plots, wherein the respective one or more voltage ranges and one or more temperature ranges correspond to respective substantially linear portions of operating points on the first and the second operating plots; and in the first stage, determining respective first and second voltage sensitivity coefficients and respective first and second temperature sensitivity coefficients corresponding to the pair of ring oscillators.

In addition, the method also includes: in a second stage, obtaining first and second ring oscillator frequencies, wherein the first and second ring oscillator frequencies correspond to first and second count quantities in a measurement time period; and in the second stage, determining a voltage range and a temperature range of the one or more voltage ranges and one or more temperature ranges on the first and second operating plots.

Moreover, the method includes: in the second stage, determining a voltage deviation from a determined intended operating voltage based on the determined respective first and second voltage sensitivity coefficients and the determined respective first and second temperature sensitivity coefficients.

Moreover, the method includes: in the second stage, determining a temperature deviation from a predetermined reference temperature based on the determined respective first and second voltage sensitivity coefficients and the determined respective first and second temperature sensitivity coefficients.

The above-referenced summary section is provided to introduce a selection of concepts in a simplified form that are further described below in the detailed description section. Additional concepts and various other implementations are also described in the detailed description. The summary is not intended to identify key features or essential features of the claimed subject matter, nor is it intended to be used to limit the scope of the claimed subject matter, nor is it intended to limit the number of inventions described herein. Furthermore, the claimed subject matter is not limited to implementations that solve any or all disadvantages noted in any part of this disclosure.

### BRIEF DESCRIPTION OF THE DRAWINGS

The present technique(s) will be described further, by way of example, with reference to embodiments thereof as illustrated in the accompanying drawings. It should be understood, however, that the accompanying drawings illustrate only the various implementations described herein and are not meant to limit the scope of various techniques, methods, systems, or apparatuses described herein.

FIG. 1 illustrates a diagram in accordance with implementations of various techniques described herein.

FIG. 2 illustrates a diagram in accordance with implementations of various techniques described herein.

FIGS. 3A-3B illustrate diagrams in accordance with implementations of various techniques described herein.

FIG. 4 illustrates a diagram in accordance with implementations of various techniques described herein.

FIG. 5 illustrates a diagram in accordance with implementations of various techniques described herein.

FIG. 6 illustrates a graphical representation in accordance with implementations of various techniques described herein.

FIG. 7 illustrates a graphical representation in accordance with implementations of various techniques described herein.

FIG. 8 is a block diagram in accordance with implementations of various techniques described herein.

FIG. 9 is a block diagram in accordance with implementations of various techniques described herein.

FIG. 10 is a block diagram in accordance with implementations of various techniques described herein.

FIG. 11 is a block diagram of a computer system in accordance with implementations of various techniques described herein.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### DETAILED DESCRIPTION

Advantageously, systems and methods of the present disclosure allow for real-time temperature and voltage profiling of various specific areas in a processing unit (e.g., digital circuit block) (e.g., CPU, GPU, NPU etc.). In certain implementations, advantageously, inventive aspects include utilizing a pair of ring oscillators (e.g., two or more ring oscillators) as a “hotspot profiler” having different characteristics (e.g., different respective relationships between the ring oscillator frequency and local supply voltage (e.g., VDD-VSS) and temperature, including different threshold voltages (VT) to cause such differences) with reference to voltage and temperature. In doing so, for example, a unique combination of the two ring oscillator frequencies (for a combination of temperature and voltage supply) may be determined.

As one example use case, it may be known or expected that a “hotspot” (e.g., a limited area with higher temperatures) would occur in a processor (i.e., processor unit) at a particular specific area. For instance, such a hotspot may occur near a vector processing unit of processor. In certain examples, a vector processing unit may be designed to perform more than two calculations on floating point vectors (e.g., one dimensional arrays of 32-bit or larger numbers) simultaneously. The vector processor unit can be a processor element with built-in instructions that is designed and configured to: perform multiple calculations on floating-point vectors (one-dimensional arrays of 32-bit or larger numbers) simultaneously, having at least one vector arithmetic logic unit; perform more than four 64-bit or larger-floating point operation results per cycle; or to perform more than eight 16-bit fixed-point multiply-accumulate results per cycle (e.g., digital manipulation of analog information that has been previously converted into digital form, also known as digital “signal processing”). Hence, in implementations, a hotspot profiler (HSP) circuitry (e.g., such as described herein) may be integrated proximate the vector processing unit. Similarly, in various implementations, such HSP circuitry may be included in various positions in the processing unit based on the type of workload requirements and/or environmental conditions.

According to certain examples, it may be determined that hotspots may exist somewhere in the processor. While an analog temperature sensor, (e.g., based on on-junction current characteristics) which may be located on the edge of the processor may inform an operator (i.e., designer or computer-based decision-making authority), that, for example, the processor is running at 80° C. (degrees Celsius), a “hotspot” inside the processor may be 10° C. more at 90° C. Advantageously, by utilizing the inventive systems and methodologies, the operator can make considerations in dynamic voltage and frequency scaling (DVFS) decisions (related to power and thermal management of the integrated circuit) based on the real-time temperature at various individual areas (i.e., points, zones) as ascertained by the inventive HSP and related methodologies. By doing so, based on the inventive aspects (as described herein), the DVFS may adjust power and/or speed settings on a computing device's various processors, controller chips and peripheral devices to optimize resource allotment for tasks and maximize power savings.

In contrast, in the absence of the inventive aspects, the operator would instead have to keep margins to accommodate excessive temperature in, e.g., maps/power vector units across all locations in the processing unit. Consequently, for example, if there was a possibility of a hotspot temperature being at, for example, 20° C. more than a temperature hub for a corner use-case, the operator would likely provide a 20° C. guard-band, for example, to allocate for an increased temperature operation of 20° C. As one would appreciate, such an approach would not be optimal as it would lead to inefficiency in power usage to maintain a given performance.

Advantageously, such inventive aspects allow for the capability to profile the temperature of a logic circuit. Hence, run-time decision making can be based on either the HSP itself or an analog temperature sensor located some distance away (e.g., for a use-case of hot-spot profile during IC characterization). Such a capability is consequential since ring oscillator frequency would also be subject to ageing (wear out), which may change characteristics over time and require re-calibration in-field, or shifts in usage of a particular component to an ageing sensor used in the field.

Nevertheless, according to inventive aspects, when the operator can account for real-time impact due to a software workload and environmental conditions, the operator and system is better able to plan for such usage. For instance, if it can be known of that temperature of certain location of a processing unit is, for example, 10° C. more and not 20° C. more (as estimated via a guard-band approach) than the reference temperature at the edge of the processor, the DVFS decision-making capacity can be different (and better optimized) at 90° C. than at 100° C. and better handle the real-time temperature. For example, the system may still “run” at a higher voltage and generate more heat if and until the temperature reaches a maximum safe operating temperature of, for example, 110° C.

In one example, if it is known that real-time operation is at 100° C., and the “headroom” is already much less than at 90° C., the DVFS can ensure the operation of the processing unit would be more adept, for example, with respect to voltage and frequency. Accordingly, the inventive aspects (as described herein) can provide significant benefits by accurately profiling across different precise locations in real-time (e.g., every 1 millisecond (ms), 5 ms).

In certain examples, with respect to a GPU or an NPU implementation, the workload may indeed demand significantly higher performance/processing capability, for example, for gaming resolution or neural network-based machine learning. As a result, the temperature would be optimized to run within limits and therefore not run at the same performance (e.g., the processor would be configured to operate at a fixed baseline voltage) to avoid thermal runaway or prevent timing errors to preserve long-term reliability when operating outside design specifications. Hence, for example, in doing so, as a trade-off, the operation would optimize performance and maintain critical reliability.

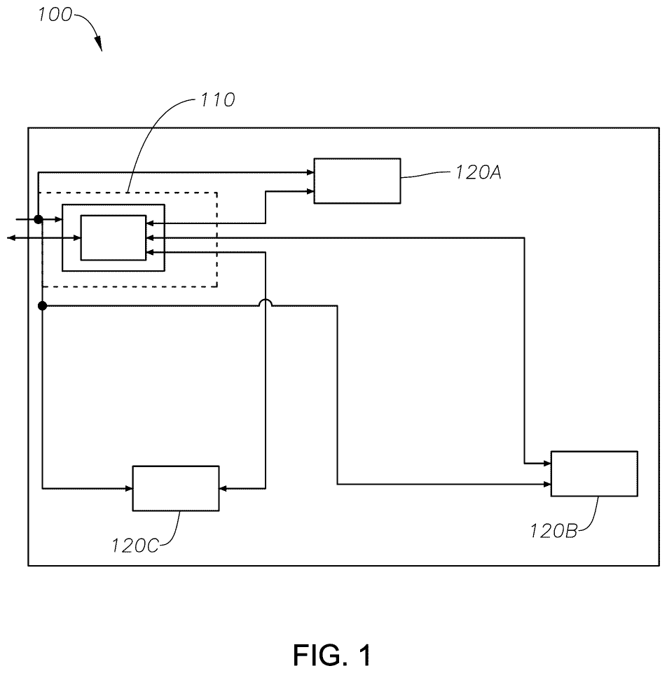

FIG. 1 illustrates an example diagram of a processing unit 100 in accordance with various implementations described herein. As illustrated, the processing unit 100 may include or be a portion of digital integrated circuitry of a central processing unit (CPU), a graphics processing unit (GPU), or a neural processing unit.

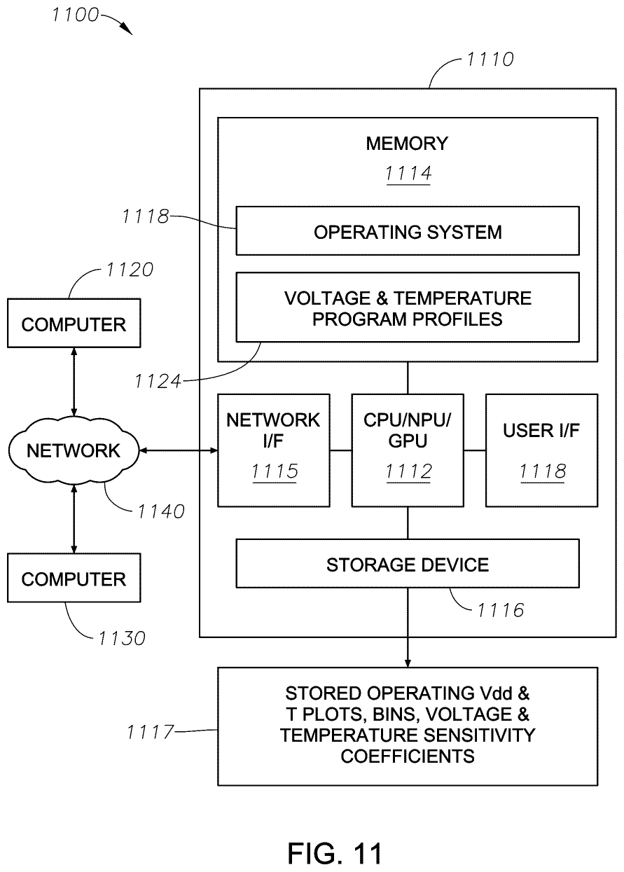

In certain implementations, at different and predetermined specific areas (e.g., locations, zones) of the processing unit 100, hotspot profiler (HSP) circuitry 120a, 120b, 120c, etc. may be positioned for computation using precision temperature and voltage profiling of the processing unit at the specific areas, and to transmit oscillator counts for a measurement period to an interface 110 (e.g., a monitor group interface) of the processing unit 110. The interface 110, in turn, would be configured to utilize or transmit raw “counts” (as described in greater detail in later paragraphs) for evaluation (e.g. by computer system 1100 as described with reference to FIG. 11) to be subsequently used as profiling data for dynamic voltage and frequency scaling (DVFS). By doing so, firmware may adjust DVFS or other power control settings to adjust power on a computing device's various processors, controller chips and peripheral devices to optimize resource allotment for tasks and maximize power saving when those resources are not needed. In certain examples, the interface 110 utilizes a serial bus protocol to communicate with the HSP.

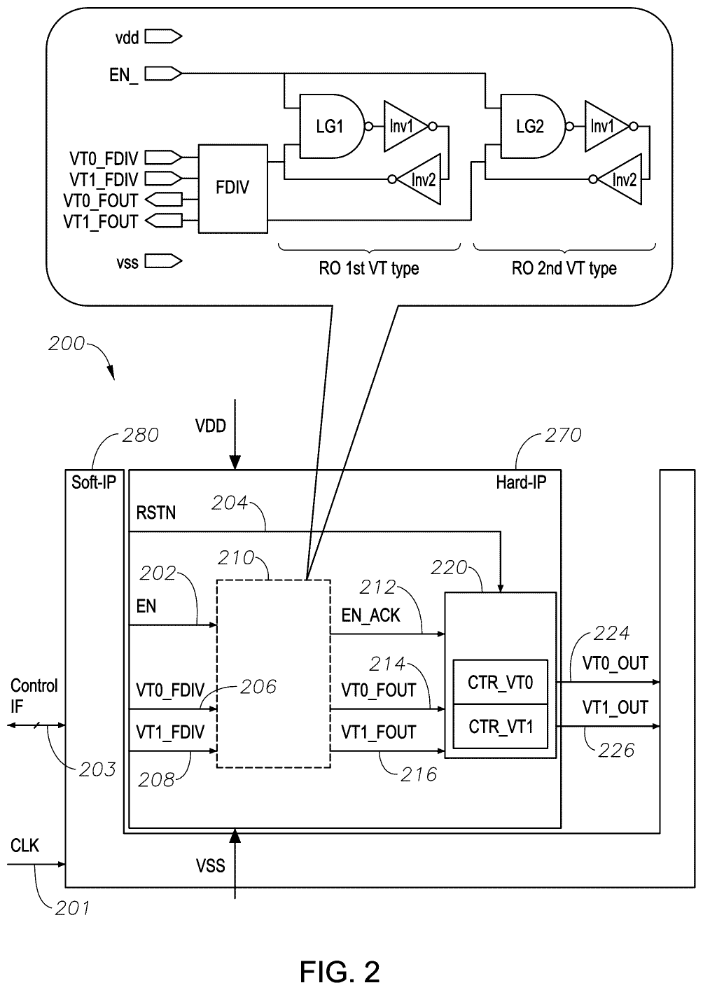

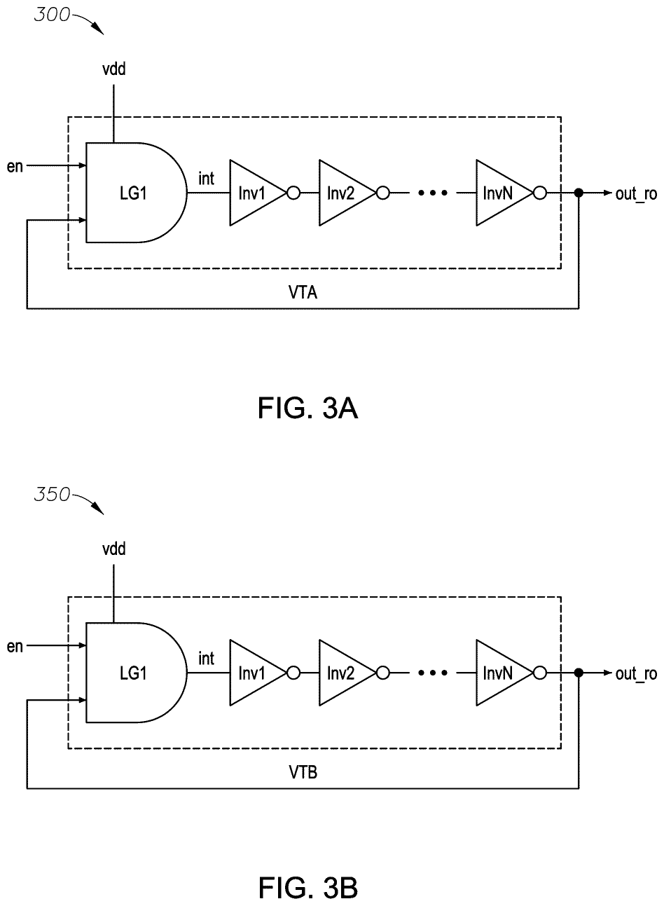

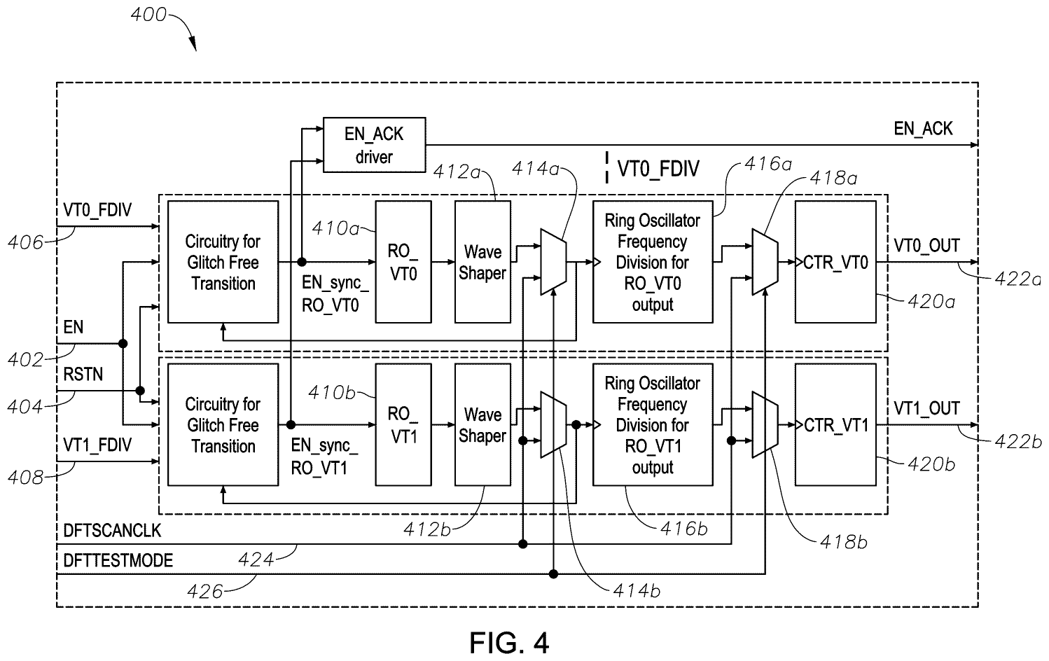

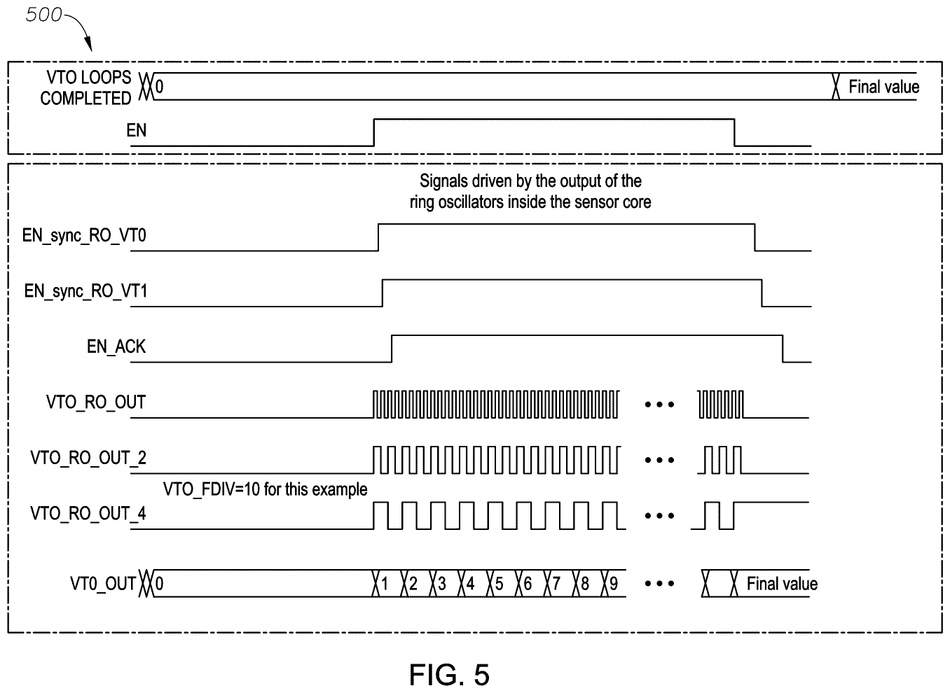

FIG. 2 illustrates an example portion of HSP 200 (i.e., HSP circuitry) corresponding to one HSP circuitry 120 as described with reference to FIG. 1, and in accordance with various implementations described herein. As illustrated, in some implementations, the HSP 200 may include a sensor core 210 and a counter block 220. As shown, an enable signal (EN) 202, a reset signal (RSTN) 204, VT0_FDIV 206, VT1_FDIV 208 are generated and provided from outside of the HSP 200 (e.g., the interface 110 with reference to FIG. 1) and transmitted to the HSP 200. These signals are described in greater detail with reference to FIG. 5. From the HSP 200, the EN_ack signal 212, a first programmable division VT0_FOUT 214, and a second programmable division VT1_FOUT 216 are transmitted to the counter block 220 (e.g., including counters for the first and second programmable divisions VT0 and VT1). As such, the counter block 220 can be configured to receive a divided block from the sensor core 210. In one example implementation, the sensor core 210 is described with greater detail with reference to FIG. 4. Also, as illustrated, to illustrate a portion of the sensor core 210, the bubble diagram shows a coupling of a pair of ring oscillators (RO), each with a different threshold voltage (i.e., different VT type). In one example implementation, the ring oscillators (RO) are described with greater detail with reference to FIGS. 3A-3B. The configuration, as illustrated, allows for capability to measure “counts” (i.e., VT0_OUT 224 and VT1_OUT 226) (as described in greater detail in below paragraphs).

In various implementations, as shown in FIG. 2, a hard macro (i.e., Hard-IP) 270 can be configured to interface to a Soft-IP wrapper (i.e., Soft-IP) 280 defined using register-transfer level (RTL). The Soft-IP wrapper 280 can include control interface signals 203, and logic generating hardware control signals to enable the ring oscillators (i.e., EN 202) and reset the counters (i.e. RSTN 204). Further, the duration for which the ring oscillators can be enabled is controlled within the Soft-IP wrapper 280 based on a period of a clock signal (CLK) 201.

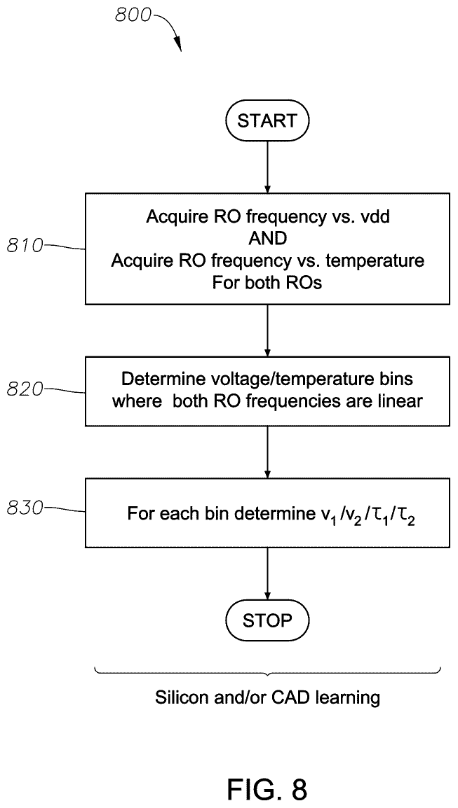

FIGS. 3A-3B illustrate example diagrams 300, 350 of sensor core 210 circuitry having ring oscillator (RO) configurations in accordance with implementations described herein. As illustrated, the HSP circuitry may be configured with a pair of ring oscillators (RO) 300, 350 that operate as performance sensing circuitry to provide output oscillating frequencies related to detecting variation of performance of a set of inverters, such as, e.g., Inv1, Inv2, . . . , InvN. Thus, the ring oscillator (RO) 300, 350 may provide the set of inverters (Inv1, Inv2, . . . , InvN) as an inverter delay stage that is adapted to provide the output oscillating frequency (out_ro) as an output RO signal. As may be appreciated, the methodology, as described with reference to FIGS. 8, 9, and 10, would require a pair of ring oscillators (RO) being trained in conjunction. In certain implementations, the oscillation frequency of the pair of RO 300, 350 would have different sensitivity towards voltage and temperature.

In certain implementations, the ring oscillator (RO) 300, 350 may include the inverter delay stage, e.g., set of inverters (Inv1, Inv2, . . . , InvN), interposed between an input logic gate (LG1), such as, e.g., an AND gate, and the output (out_ro). In various instances, the inverter delay stage (Inv1, Inv2, . . . , InvN) may include any even number of inverter stages that are coupled in series, with only one condition in that the ring oscillator (RO) provides the oscillating output signal (out_ro). The inverter delay stage (Inv1, Inv2, . . . , InvN) may provide the output oscillating signal (out_ro) as a feedback signal to the input logic gate (LG1), which receives multiple input signals, e.g., including enable signal (en) and the output oscillating signal (out_ro) as a feedback input signal. As such, the input logic gate (LG1) receives input signals (en) and the oscillating output signal and then provides an intermediate signal (int) to the inverter delay stage (Inv1, Inv2, . . . , InvN). Also, in various applications, the input logic gate (LG1) may be implemented with different logic gates, including, e.g., AND/NAND gates, OR/NOR gates, etc. In other instances, the inverter delay stage may be implemented with any other logic structure that provides an inverting output, such as, e.g., using various logic stages. Also, in still other instances, the ring oscillator (RO) may be any other type of voltage-controlled oscillator that provides similar behavior and/or characteristics.

FIG. 4 illustrates an example portion of the sensor core 400 (i.e., sensor core circuitry) corresponding to the sensor core 210 of one HSP circuitry 120 as described with reference to FIGS. 1 and 2, and in accordance with various implementations described herein. FIG. 5 illustrates an example operation 500 of the sensor core 400 as waveforms. As illustrated, FIG. 4 depicts one common signal (EN) 402 that is passed to the circuit for glitch free transition to generate enable signals (e.g., EN_sync_RO_VT0 and EN_sync_RO_VT1) and enables both ring oscillators (e.g., RO_VT0 and RO_VT1) 410a, 410b. The respective output signals from the ring oscillators (RO) 410a, 410b are each sent to a wave shaper circuit 412a, 412b (e.g., circuitry of two inverters) to correct slope with minimal capacitive “loading” on the ring oscillators 410a, 410b. Next each of the RO clock signals are fed through respective first multiplexers 414a, 414b and then to respective frequency dividers 416a, 416b. In various implementations, the frequency dividers 416a, 416b are configured to divide each output clock by using the information present in VT0_FDIV 406 and VT1_FDIV 408. For instance, the output signals of the respective frequency dividers 416a, 416b could be the same as the input signals or divided by 2, 4, or other multiples (as shown as the signal response of VT0_RO_OUT, VT0_RO_OUT2, and VT0_RO_OUT4 in FIG. 5). The resultant signals are then sent through respective second multiplexers 414a, 414b, and then through respective counters 420a, 420b. The first and the second multiplexer stages may be used for Design for Test (DFT) purposes, where a separate clock signal DFTSCANCLK 424 is used to drive the 416a 416b 420a and 420b blocks. In this manner, with reference to FIGS. 4 and 5, an initial enable signal can be configured to start oscillating (e.g., the EN signal goes “high”), and output a respective clock signal to a respective divider, and then to a counter that starts counting. The counter 420a, 420b would then output a running count 422a, 422b (VT0_Out and VT1_Out) as final values (as shown in FIG. 5).

In certain implementations, when the circuit is disabled, the signal would get resynchronized with the respective RO clocks, and the VT0_OUT and VT1_OUT would become static. Hence, for an enable cycle, two counts would be present (i.e., Count 1 and Count 2) that have a have linear relationship (as described in below paragraphs) with the frequency of the ring oscillators over a fixed period. Hence, the frequency can govern the count, and can be utilized accordingly.

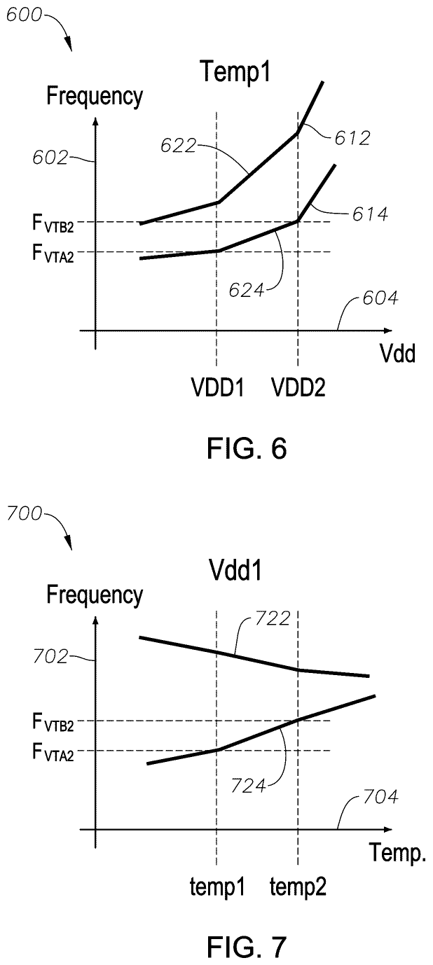

FIG. 6 illustrates a graph 600 (i.e., a first operating plot) of ring oscillator frequency (on the Y-axis) as function of supply voltage (Vdd) (on the X-axis). FIG. 7 illustrates a graph 700 (i.e., a second operating plot) of ring oscillator frequency (on the Y-axis) as function of temperature (T) (on the X-axis). As may be appreciated, for both graphs 600, 700, the ring oscillator frequency corresponds to a quantity of counts for a given measurement period (i.e., a sample window). As observed, curves 612, 614 and curves 712, 714 represent a “non-linear” behavior of two example ring oscillators having distinct threshold voltages (VT) (i.e., VTA, VTB) (as described in above paragraphs) over across a wide comprehensive range of respective voltages and temperatures. However, if only a limited range of respective voltages and temperatures are considered, it can be observed that for the respective limited range, the behavior is in fact a substantially linear relationship (and can be expressed as a slope). Hence, for example, in FIG. 6, if the entire range of Vdd can be between 500 and 1000 millivolts (mV), for the first ring oscillator frequency, a limited voltage range 622 can be “pinned” to start at VDD1 (e.g., at 800 mV) until VDD2 (e.g., 900 mV) for curve 612. Similarly, for the second ring oscillator frequency, a limited voltage range 624 can be “pinned” to start at VDD1 (e.g., at 800 mV) until VDD2 (e.g., 900 mV) for curve 614.

Likewise, for example, in FIG. 7, if the entire range of temperature (T) can be between −40° C. and 150° C., for the first ring oscillator frequency, a limited temperature range 722 can be “pinned” to start at a first temperature (temp 1, e.g., 80° C.) until a second temperature (temp 2, e.g., 120° C.) for curve 712. Similarly, for the second ring oscillator frequency, a limited temperature range 724 can be “pinned” to start at the first temperature (temp 1) until the second temperature (temp 2) for curve 714.

In doing so, for each limited range (i.e., particular voltage and temperature “bins”), voltage and temperature sensitivity coefficients (i.e., v₁, v₂, τ₁, τ₂) can be developed corresponding to respective slopes of the respective substantially linear portions of the curves (e.g., 622, 624, 722, 724). Advantageously, inventive schemes and techniques, as described herein, in certain aspects, “look” for substantially linear portions (over longer ranges, if possible) in behavior of the frequency as a function of temperature and the same frequency as a function of the voltage.

As may be appreciated, based on the above, the following expressions can be considered to map the two ring oscillators:

$${C}_{1} = {v}_{1} * Δ Vdd + {τ}_{1} * Δ T + {k}_{1}$$

$${C}_{2} = {v}_{2} * Δ Vdd + {τ}_{2} * Δ T + {k}_{2}$$

In certain implementations, as may be appreciated, the count (C₁, C₂) of a ring oscillator (RO) is equivalent to the frequency component, where C₁, C₂ is a count of ring oscillator frequency corresponding to a running count as depicted in counter 220 (in FIG. 2) and outputs 422a, 422b (VT0_Out and VT1_Out) as final values (in FIG. 5). Hence, the C₁ and C₂ quantities can be measured during runtime on silicon.

In various implementations, both ring oscillators can be “laid out” to experience the same supply voltage and that the counts for both ring oscillators would be measured simultaneously. For example, if such measurements were taken in sequence, the measured counts may be skewed by different transient voltage and a corresponding inference of temperature would be compromised.

As described, the voltage sensitivity coefficients (v₁, v₂) and temperature sensitivity coefficients (τ₁, τ₂) may be quantified via silicon characterization (i.e., silicon learning) or more computer automated design using spice simulations, based on a determination of the respective limited range (i.e., bin) slopes. For this objective, according to one example, an extensive silicon characterization (i.e., silicon learning) (e.g., training of a neural network, training a machine learning model) is conducted to “learn” (“linearize”) the operational behavior of the two of ring oscillators as described herein. In the expressions, k₁ and k₂ are constants (e.g., predetermined from test where, for example, ΔVdd and ΔT are set to 0 values (or any other known values in other cases). In such a test scenario, the value of the counts would be equal to k₁ and k₂.

As an example, ΔVdd is a deviation (i.e., change) in voltage with respect to a known voltage (i.e., a reference voltage), and ΔT is a deviation (i.e., change) in temperature with respect to a known temperature (i.e., a reference temperature). Hence, if a reference voltage is set at 800 mV and a reference temperature is 90° C., it is ascertained via silicon characterization (i.e., silicon learning, “linearization”) or more computer automated design that the voltage sensitivity coefficient is 2 Counts/mV and the temperature sensitivity coefficient is 2Counts/2° Crespectively, for that particular measurement bin, the unknown ΔT and ΔVDD may be determined as well.

At silicon, the number of counts can be measured via the HSP and is a function of the expression. While the ΔVdd and ΔT are unknowns, each of the other quantities may be developed, and since there are two expressions having different threshold voltages with two unknowns, both quantities can be ascertained. For instance, by silicon characterization, for the voltage sensitivity coefficient, the effective slope of each curve can be determined; e.g., how much frequency/how much do counts vary if there is a change supply voltage (e.g., by 10 mV) Such quantities can be ascertained by silicon characterization as well and/or from CAD and determined from silicon. Similarly, for the temperature sensitivity coefficient as determined from silicon would be the sensitivity of RO to temperature.

Accordingly, the expressions can be rewritten as:

$$Δ VDD = \frac{{τ}_{2}}{DENOM} * C 1 - \frac{{τ}_{1}}{DENOM} * C 2 + \frac{{τ}_{1} {k}_{2} - {τ}_{2} {k}_{1}}{DENOM}$$

$$Δ VDD = {R}_{C 1} * C 1 + {R}_{C 2} * C 2 + {R}_{VDD}$$

$$Δ T = \frac{{v}_{2}}{DENOM} * C 1 - \frac{{v}_{1}}{DENOM} * C 2 + \frac{{v}_{1} {k}_{2} - {v}_{2} {k}_{1}}{DENOM}$$

$$Δ T = {Q}_{C 1} * C 1 + {Q}_{C 2} * C 2 + {Q}_{T}$$

$$DENOM = {τ}_{1} * {v}_{2} - {τ}_{2} * {v}_{1}$$

In other implementations, silicon characterization and CAD modeling may be obtained from simulation and silicon measurement. For example, such characterization and modeling can be an example variation of the functions of voltage and time (f (V,t)) and can be “fit” with an analytic equation or represented as piece-wise linear. In such cases, the characterization and/or modeling would not be limited to two plots, for example, but rather can be an N×M matrix of voltage and temperature conditions, either fully or partially populated.

As may be appreciated, the f (V,T) characteristics can be obtained for a plurality of conditions and, also, be described by various analytical functions. Advantageously, inventive aspects as described herein allow for a relatively simplified approximation (example linear) around an intended operation point, such that these functions can be replaced to determine an actual operating point as a deviation from the intended operating point. Hence, the intended operating point is the central goal for such linearization.

FIG. 8 illustrates an example procedure 800 for silicon characterization and/or CAD learning (i.e., silicon “learning”). At step 810, in a first stage, Acquire RO frequency vs. Vdd and Acquire RO frequency vs. temperature for both ring oscillators. For instance, the step includes: obtaining (e.g., measuring, acquiring), for a pair of ring oscillators of a hotspot profiler of a processing unit, a plurality of operating points of a first operating plot, wherein the first operating plot corresponds to a plurality of ring oscillator frequencies as a function of a plurality of supply voltage; and obtaining (e.g., measuring, acquiring), for the (same) pair of the ring oscillators of the hotspot profiler of the processing unit, a plurality of operating points of a second operating plot, wherein the second operating plot corresponds to the (same) plurality of the ring oscillator frequencies as a function of a plurality of temperatures.

At step 820, in a first stage, determine voltage and temperature bins where both RO frequencies are linear. For instance, the step involves: determining respective one or more voltage ranges and one or more temperature ranges (i.e., voltage bins and temperature bins) on the first and second operating plots, wherein the respective one or more voltage ranges and one or more temperature ranges correspond to respective substantially linear portions of operating points (of the pluralities of ring oscillator frequencies as functions of the pluralities of supply voltage and the pluralities of temperature) on the first and the second operating plots.

At step 830, for each bin determine voltage and temperature sensitivity coefficients. v₁, v₂, τ₁, and τ₂. For instance, in a first stage (i.e., a learning phase, “linearization” phase), determining, by at least one of silicon characterization and computer-automated design (CAD) modeling, respective first and second voltage sensitivity coefficients (i.e., v₁, v₂) and respective first and second temperature sensitivity coefficients (i.e., τ₁, τ₂) (corresponding to a pair of ring oscillators over a sampling window (i.e., a measurement field)).

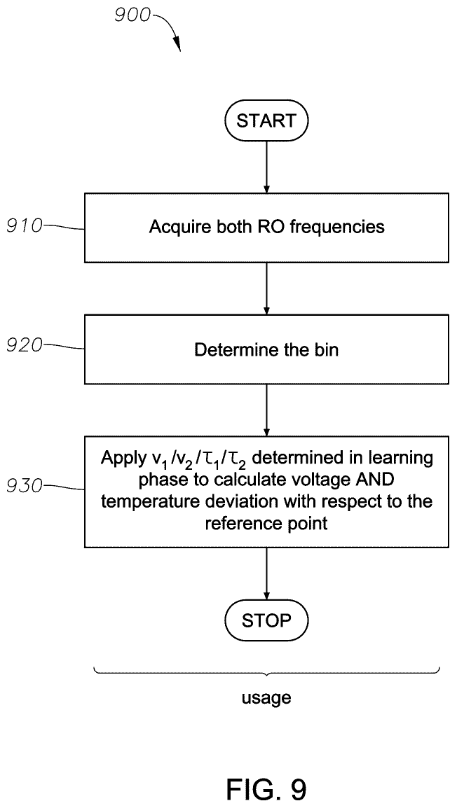

FIG. 9 illustrates an example procedure 900 for usage (in a usage stage) of the voltage and temperature sensitivity coefficients. At step 910, in a second stage, acquire both RO frequencies. For instance, the step involves: obtaining first and second ring oscillator (RO) frequencies, wherein the first and second ring oscillator (RO) frequencies correspond to first and second (measured) count quantities in a measurement time period.

At step 920, in a second stage, determine the bin. For instance, the step involves: determining a (particular) voltage range and a (particular) temperature range on respective first and second operating plots (i.e., determining the bin), wherein: the first operating plot corresponds to a plurality of ring oscillator frequencies as a function of a plurality of supply voltage, and the second operating plot corresponds to the plurality of ring oscillator frequencies as a function of a plurality of temperatures.

At step 930, in a second stage, apply v₁/v₂/τ₁/τ₂ determined in learning phase to calculate voltage AND temperature deviation with respect to the reference point. For instance, the step involves: in a second stage (i.e., a usage phase), computing a voltage deviation (ΔVdd) (i.e., a voltage difference) and determining a temperature deviation (ΔT) (i.e., a temperature difference) from respective operating points (i.e., a reference voltage and respective reference temperature) of first and second frequency operating plots based on the determined respective first and second voltage sensitivity coefficients and the determined respective first and second temperature sensitivity coefficients.

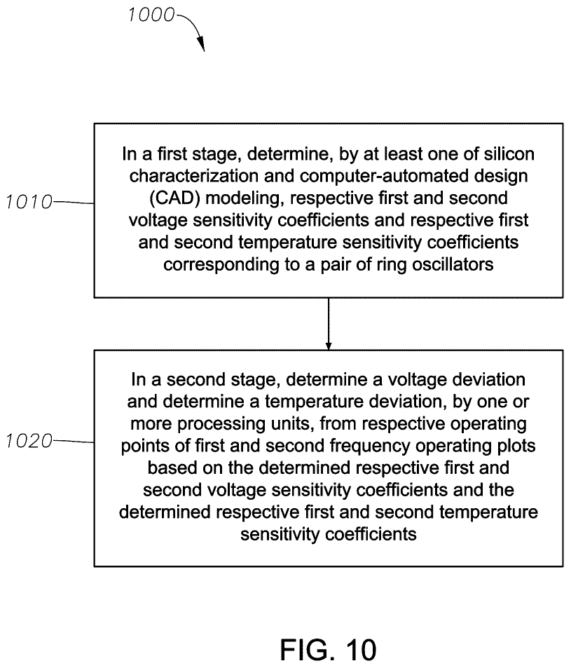

FIG. 10 illustrates an example method 1000 for profiling of temperature and voltage by one or more HSPs configured to measure temperature and voltage at different locations within a processor.

At step 1010, in a first stage (i.e., a learning phase, “linearization” phase), determining, determining, by at least one of silicon characterization and computer-automated design (CAD) modeling, respective first and second voltage sensitivity coefficients (i.e., v₁, v₂) and respective first and second temperature sensitivity coefficients (i.e., τ₁, τ₂) (corresponding to a pair of ring oscillators over a sampling window (i.e., a measurement field)). For instance, such a step may be performed with reference to implementations as described in FIGS. 1-9 and FIG. 11.

At step 1020, in a second stage (i.e., a usage phase), computing a voltage deviation (ΔVdd) (i.e., a voltage difference) and computing a temperature deviation (ΔT) (i.e., a temperature difference) from respective operating points of first and second operating plots based on the determined respective first and second voltage sensitivity coefficients and the determined respective first and second temperature sensitivity coefficients.

Advantageously, for instance, the computer system 1100 (as described with reference to FIG. 10) may generate a temperature and voltage profile for the processing unit 100. The profile may be based on the determined voltage and temperature sensitivity coefficients, and expressions of the two ring oscillators (with respect to frequency, voltage, and temperature).

FIG. 11 is a diagram depicting the computer system 1100 (e.g., networked computer system and/or server) for the example processing unit 100 (as described in FIG. 1), according to one implementation. FIG. 11 illustrates example hardware components in the computer system 1100 that may be used to determine and/or characterize (e.g., adjust, “linearize”) voltage and temperature sensitivity coefficients for HSPs of the processing unit. The computer system 1100 includes a computer 1110, which may be implemented as a server or a multi-use computer that is coupled via a network 1140 to one or more networked (client) computers 1120, 1130. In certain implementations, the methods 800, 900, and 1000 may be stored as program code (i.e., silicon characterization program 1124) in memory that may be performed by the computer 1110, the computers 1120, 1130, other networked electronic devices (not shown) or a combination thereof. In some implementations, the program 1124 may read input data and provide controlled output data to various connected computer systems including an associated processor system. In certain implementations, each of the computers 1110, 1120, 1130 may be any type of computer, computer system, or other programmable electronic device. Further, each of the computers 1110, 1120, 1130 may be implemented using one or more networked (e.g., wirelessly networked) computers, e.g., in a cluster or other distributed computing system. Each of the computers 1110, 1120, 1130 may be implemented within a single computer or programmable electronic device, e.g., a laptop computer, a hand-held computer, phone, tablet, etc. Advantageously, in example implementations, one or more of the computers 1110, 1120, and 1130 of the computer system 1100 may generate a temperature and voltage profile of a location on the processing unit 100.

In certain implementation, the computer 1100 includes a CPU, GPU, or NPU 1112 having at least one hardware-based processor coupled to a memory 1114. The memory 1114 may represent random access memory (RAM) devices of main storage of the computer 1110, supplemental levels of memory (e.g., cache memories, non-volatile or backup memories (e.g., programmable or flash memories)), read-only memories, or combinations thereof. In addition to the memory 1114, the computer system 13100 may include other memory located elsewhere in the computer 1110, such as cache memory in the CPU/NPU/GPU 1112, as well as any storage capacity used as a virtual memory (e.g., as stored on a storage device 1116 or on another computer coupled to the computer 1110). The memory 1114 may include one or more programs 1124, and the storage device 1316 may include substantially linear portions on respective frequency-based operating plots, bins, and related coefficients 1317.

The computer 1110 may further be configured to communicate information externally. To interface with a user or operator (e.g., aerodynamicist, engineer), the computer 1110 may include a user interface (I/F) 1118 incorporating one or more user input devices (e.g., a keyboard, a mouse, a touchpad, and/or a microphone, among others) and a display (e.g., a monitor, a liquid crystal display (LCD) panel, light emitting diode (LED), display panel, and/or a speaker, among others). In other examples, user input may be received via another computer or terminal. Furthermore, the computer 1110 may include a network interface (I/F) 1120 which may be coupled to one or more networks 1140 (e.g., a wireless network) to enable communication of information with other computers and electronic devices. The computer 1110 may include analog and/or digital interfaces between the CPU 1112 and each of the components 1114, 1116, 1118 and 1120. Further, other non-limiting hardware environments may be used within the context of example implementations.

The computer 1110 may operate under the control of an operating system 1126 and may execute or otherwise rely upon various computer software applications, components, programs, objects, modules, data structures, etc. (such as the programs 1124 and related software). The operating system 1126 may be stored in the memory 1114. Operating systems include, but are not limited to, UNIX® (a registered trademark of The Open Group), Linux® (a registered trademark of Linus Torvalds), Windows® (a registered trademark of Microsoft Corporation, Redmond, WA, United States), AIX® (a registered trademark of International Business Machines (IBM) Corp., Armonk, NY, United States) i5/OS® (a registered trademark of IBM Corp.), and others as will occur to those of skill in the art. The operating system 1126 and the AOA program 1124 in the example of FIG. 11 are shown in the memory 1114, but components of the aforementioned software may also, or in addition, be stored at non-volatile memory (e.g., on storage device 1116 (data storage) and/or the non-volatile memory (not shown). Moreover, various applications, components, programs, objects, modules, etc. may also execute on one or more processors in another computer coupled to the computer 1110 via the network 1140 (e.g., in a distributed or client-server computing environment) where the processing to implement the functions of a computer program may be allocated to multiple computers 1120, 1130 over the network 1140.

Aspects of the present disclosure may be incorporated in a system, a method, and/or a computer program product. The computer program product may include a computer-readable storage medium (or media) having computer-readable program instructions thereon for causing a processor to carry out aspects of the present disclosure. The computer-readable storage medium can be a tangible device that can retain and store instructions for use by an instruction execution device. The computer-readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer-readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer-readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire. For example, the memory 1114, the storage device 1116, or both, may include tangible, non-transitory computer-readable media or storage devices.

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and procedural programming languages, such as the “C” programming language or similar programming languages. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry, field-programmable gate arrays (FPGA), or programmable logic arrays (PLA) may execute the computer-readable program instructions by utilizing state information of the computer-readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, such that the instructions, which execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

In the following description, numerous specific details are set forth to provide a thorough understanding of the disclosed concepts, which may be practiced without some or all of these particulars. In other instances, details of known devices and/or processes have been omitted to avoid unnecessarily obscuring the disclosure. While some concepts will be described in conjunction with specific examples, it will be understood that these examples are not intended to be limiting.

Unless otherwise indicated, the terms “first”, “second”, etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Reference herein to “one example” means that one or more feature, structure, or characteristic described in connection with the example is included in at least one implementation. The phrase “one example” in various places in the specification may or may not be referring to the same example.

Illustrative, non-exhaustive examples, which may or may not be claimed, of the subject matter according to the present disclosure are provided below. Different examples of the device(s) and method(s) disclosed herein include a variety of components, features, and functionalities. It should be understood that the various examples of the device(s) and method(s) disclosed herein may include any of the components, features, and functionalities of any of the other examples of the device(s) and method(s) disclosed herein in any combination, and all of such possibilities are intended to be within the scope of the present disclosure. Many modifications of examples set forth herein will come to mind to one skilled in the art to which the present disclosure pertains having the benefit of the teachings presented in the foregoing descriptions and the associated drawings.

Therefore, it is to be understood that the present disclosure is not to be limited to the specific examples illustrated and that modifications and other examples are intended to be included within the scope of the appended claims. Moreover, although the foregoing description and the associated drawings describe examples of the present disclosure in the context of certain illustrative combinations of elements and/or functions, it should be appreciated that different combinations of elements and/or functions may be provided by alternative implementations without departing from the scope of the appended claims. Accordingly, parenthetical reference numerals in the appended claims are presented for illustrative purposes only and are not intended to limit the scope of the claimed subject matter to the specific examples provided in the present disclosure.

What is claimed is:

1. A method comprising:
in a first stage, determining respective first and second voltage sensitivity coefficients and respective first and second temperature sensitivity coefficients corresponding to a pair of ring oscillators; and
in a second stage, determining a voltage deviation and a temperature deviation from a predetermined reference voltage and a predetermined reference temperature respectively, based on:
the determined respective first and second voltage sensitivity coefficients; and the determined respective first and second temperature sensitivity coefficients.

2. The method of claim 1, wherein the respective first and second coefficients correspond to a correlation of ring oscillator frequency on both voltage and temperature metrics for the pair of the ring oscillators.

3. The method of claim 1, wherein the respective first and second voltage sensitivity coefficients and respective first and second temperature sensitivity coefficients are determined by at least one of silicon characterization and CAD modeling.

4. The method of claim 3, wherein, in the first stage, at least one of silicon characterization and CAD modeling comprises:
obtaining, for a pair of ring oscillators of a hotspot profiler of a processing unit, a plurality of operating points of a first operating plot, wherein the first operating plot corresponds to a plurality of ring oscillator frequencies as a function of a plurality of supply voltage; and
obtaining, for the pair of the ring oscillators of the hotspot profiler of the processing unit, a plurality of operating points of a second operating plot, wherein the second operating plot corresponds to the plurality of the ring oscillator frequencies as a function of a plurality of temperatures.

5. The method of claim 4, wherein, in the first stage, the at least one of silicon characterization and CAD modeling comprises:
determining respective one or more voltage ranges and one or more temperature ranges on the first and second operating plots, wherein the respective one or more voltage ranges and one or more temperature ranges correspond to respective substantially linear portions of operating points on the first and the second operating plots.

6. The method of claim 5, wherein, in the first stage, the at least one of silicon characterization and CAD modeling comprises:
determining, for each of the one or more voltage ranges and the one or more temperature ranges, the first and the second voltage sensitivity coefficients and the first and the second temperature sensitivity coefficients.

7. The method of claim 6, wherein the first and second voltage sensitivity coefficients and the first and second temperature coefficients correspond to respective slopes of the respective linear portions of the curves.

8. The method of claim 1, wherein:
the respective first and second voltage sensitivity coefficients and respective first and second temperature sensitivity coefficients correspond to a pair of ring oscillators; and
each ring oscillator of the pair of ring oscillators comprises a distinct threshold voltage.

9. The method of claim 1, wherein in the second stage, further comprising:
determining a voltage range and a temperature range on first and second operating plots, wherein:
the voltage range and the temperature range correspond to respective substantially linear portions of operating points on the first and the second operating plots;
the first operating plot corresponds to a plurality of ring oscillator frequencies as a function of a plurality of supply voltage, and
the second operating plot corresponds to the plurality of ring oscillator frequencies as a function of a plurality of temperatures.

10. The method of claim 1, wherein in the second stage, further comprising:
obtaining first and second ring oscillator frequencies, wherein the first and second ring oscillator frequencies correspond to first and second count quantities in a measurement time period, wherein the first and the second count quantities are acquired simultaneously in the same measurement period.

11. The method of claim 10, wherein the first count quantity comprises the combination of:
a product of the determined first voltage sensitivity coefficient and the voltage deviation;
a product of the determined first temperature sensitivity coefficient and the temperature deviation; and
a predetermined first constant.

12. The method of claim 10, wherein the second count quantity comprises the combination of:
a product of the determined second voltage sensitivity coefficient and the voltage deviation;
a product of the determined second temperature sensitivity coefficient and a temperature deviation; and
a predetermined second constant.

13. The method of claim 1, further comprising:
generating, by a hotspot profiler of a processing unit, a temperature and voltage profile corresponding to the location of the hotspot profiler based at least partially on the voltage deviation and temperature deviation.

14. The method of claim 13, further comprising:
adjusting power and speed settings of the processor unit, by dynamic voltage and frequency scaling (DVFS), based on the generated temperature and voltage profile.

15. A computer system comprising:
a processor; and
a memory accessible to the processor, the memory storing instructions that are executable by the processor to perform operations comprising:
in a first stage, determining respective first and second voltage sensitivity coefficients and respective first and second temperature sensitivity coefficients corresponding to a pair of ring oscillators; and
in a second stage, determining a voltage deviation and a temperature deviation from a predetermined reference voltage and a predetermined reference temperature respectively, based on:
the determined respective first and second voltage sensitivity coefficients; and
the determined respective first and second temperature sensitivity coefficients.

16. The computer system of claim 15, wherein the memory storing instructions that are executable by the processor to perform operations comprising:
generating, by a hotspot profiler of a processing unit, a temperature and voltage profile corresponding to the location of the hotspot profiler based at least partially on the voltage deviation and the temperature deviation.

17. The computer system of claim of claim 15, wherein the memory storing instructions that are executable by the processor to perform operations comprising:
adjusting power and speed settings of the processor unit, by dynamic voltage and frequency scaling (DVFS), based on the generated temperature and voltage profile.

18. A method comprising:
in a first stage, obtaining, for a pair of ring oscillators of a hotspot profiler of a processing unit, a plurality of operating points of a first operating plot, wherein the first operating plot corresponds to a plurality of ring oscillator frequencies as a function of a plurality of supply voltage;
in the first stage, obtaining, for the pair of the ring oscillators of the hotspot profiler of the processing unit, a plurality of operating points of a second operating plot, wherein the second operating plot corresponds to the plurality of the ring oscillator frequencies as a function of a plurality of temperatures;
in the first stage, determining respective one or more voltage ranges and one or more temperature ranges on the first and second operating plots, wherein the respective one or more voltage ranges and one or more temperature ranges correspond to respective substantially linear portions of operating points on the first and the second operating plots; and
in the first stage, determining respective first and second voltage sensitivity coefficients and respective first and second temperature sensitivity coefficients corresponding to the pair of ring oscillators.

19. The method of claim 18, further comprising:
in a second stage, obtaining first and second ring oscillator frequencies, wherein the first and second ring oscillator frequencies correspond to first and second count quantities in a measurement time period;
in the second stage, determining a voltage range of the one or more voltage ranges and a temperature range of the one or more temperature ranges on the first and second operating plots.

20. The method of claim 19, further comprising:
in the second stage, determining a voltage deviation and a temperature deviation from respective operating points of first and second frequency operating plots based on the determined respective first and second voltage sensitivity coefficients and the determined respective first and second temperature sensitivity coefficients.

21. A method comprising:
obtaining first and second ring oscillator frequencies, wherein the first and second ring oscillator frequencies correspond to first and second count quantities in a measurement time period;
determining a voltage range of one or more voltage ranges and a temperature range of one or more temperature ranges on the first and second operating plots; and
determining a voltage deviation and a temperature deviation from a predetermined reference voltage and a predetermined reference temperature respectively, based on: respective first and second voltage sensitivity coefficients, and respective first and second temperature sensitivity coefficients.
